(19) United States
(12) Patent Application Publication
(10) Pub. No.: US 2023/0337450 A1
(43) Pub. Date: Oct. 19, 2023

(54) LIGHT-EMITTING ELEMENT AND LIGHT-EMITTING DEVICE

(71) Applicant: SHARP KABUSHIKI KAISHA, Sakai City, Osaka (JP)

(72) Inventor: TAKAHIRO DOE, Sakai City, Osaka (JP)

(21) Appl. No.: 18/033,791

(22) PCT Filed: Oct. 29, 2020
(86) PCT No.: PCT/JP2020/040548

§ 371 Date: Apr. 25, 2023

(51) Int. Cl. H10K 50/115

(52) U.S. Cl. CPC H10K 50/115

(57) ABSTRACT

A light-emitting element includes: a first anode; a first cathode; and a light-emitting layer between the first anode and the first cathode, the light-emitting layer containing a first quantum dot that emits light of a first color, wherein the first quantum dot includes: a first core; and a first shell around the first core, the first shell containing a transition metal oxide.

### TECHNICAL FIELD

The present disclosure relates to light-emitting elements and light-emitting devices.

### BACKGROUND ART

Patent Literature 1 discloses an organic EL (electro-luminescence) element including a light-emitting layer including a 3-layer stack of a light-emitting sublayer that emits blue light, a light-emitting sublayer that emits green light, and a light-emitting sublayer that emits blue light.

### CITATION LIST

### Patent Literature

Patent Literature 1: Japanese Unexamined Patent Application Publication, Tokukai, No. 2016-051845

### SUMMARY OF INVENTION

### Technical Problem

The organic EL element disclosed in Patent Literature 1 requires a stack of three light-emitting sublayers to generate blue, green, and red light. With a view to restraining manufacturing cost, however, there is a demand to reduce the number of times the light-emitting layer is subjected to patterning to obtain a light-emitting layer capable of emitting light of different colors. The present disclosure, in an aspect thereof, provides a light-emitting layer capable of emitting light of different colors by a reduced number of patterning processes.

### Solution to Problem

The present disclosure, in one aspect thereof, is directed to a light-emitting element including: a first anode; a first cathode; and a light-emitting layer between the first anode and the first cathode, the light-emitting layer containing a first quantum dot that emits light of a first color, wherein the first quantum dot includes: a first core; and a first shell around the first core, the first shell containing a transition metal oxide.

### BRIEF DESCRIPTION OF DRAWINGS

FIG. 1 is an enlarged plan view of a part of a display area of a display device in accordance with an embodiment.

FIG. 2 is a cross-sectional view of the display device in accordance with the embodiment.

FIG. 3 is a schematic diagram illustrating a leak current flowing in the shell of a quantum dot in accordance with the embodiment.

FIG. 4 is a schematic diagram representing a relationship between voltage and current supplied to quantum dots in accordance with the embodiment.

FIG. 5 is a diagram representing voltages fed to quantum dots and resistance conditions of shells in accordance with the embodiment.

FIG. 6 is a diagram representing changes over time in the voltage fed to quantum dots in accordance with the embodiment.

FIG. 7 is a diagram representing a relationship between the voltage applied to a light-emitting element and the luminous intensity of the light-emitting element in accordance with the embodiment.

FIG. 8 is a diagram representing a relationship between a color-mixture ratio of red and green light, a color-mixture ratio of green and blue light, and a BT2020 coverage ratio in accordance with the embodiment.

FIG. 9 is a diagram illustrating a BT2020 coverage ratio in accordance with the embodiment.

FIG. 10 is a diagram representing an example of driving light-emitting elements by a field sequential technique in accordance with Variation Example 1 of the embodiment.

FIG. 11 is a schematic cross-sectional view of a light-emitting element in a display device in accordance with Variation Example 2 of the embodiment.

FIG. 12 is a schematic cross-sectional view of light-emitting elements in a display device in accordance with Variation Example 3 of the embodiment.

FIG. 13 is a schematic cross-sectional view of a light-emitting element in a display device in accordance with Variation Example 4 of the embodiment.

### DESCRIPTION OF EMBODIMENTS

### Embodiments

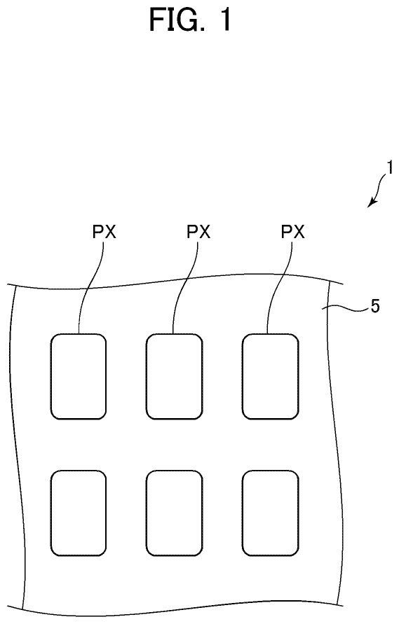

FIG. 1 is an enlarged plan view of a part of a display area 5 of a display device 1 in accordance with an embodiment. The display device 1 is an example of a light-emitting device in accordance with an aspect of the present disclosure and is, for example, a device capable of displaying images. Note that the light-emitting device in accordance with an aspect of the present disclosure is not necessarily the display device 1 and may be any device that emits light.

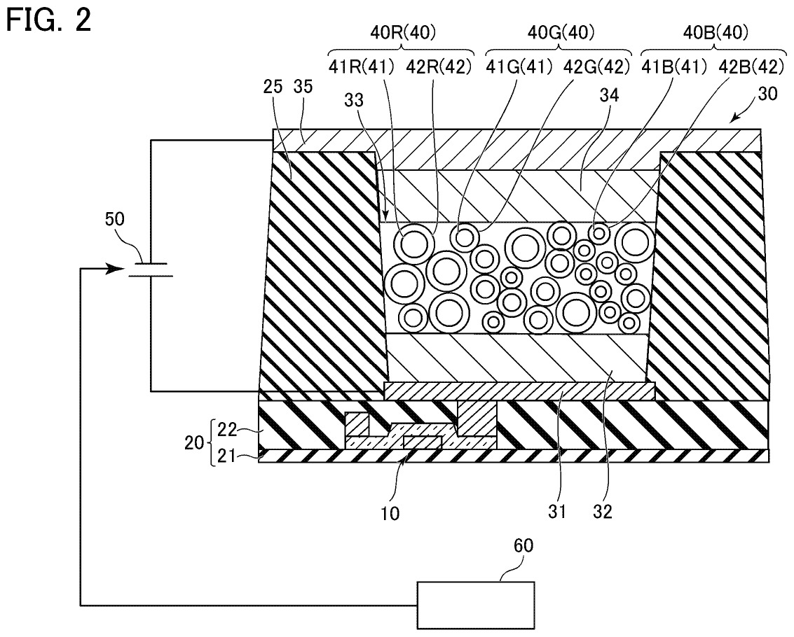

The display device 1 has, for example: a display area (display unit) 5 where images are displayed; and a frame area (not shown) shaped like a frame surrounding the display area 5. The display area 5 includes a matrix of pixels PX. Each pixel PX includes a light-emitting element 30 (see FIG. 2). In the present embodiment, the pixels PX are structured to emit light of various colors including red, green, and blue and a mixed color of these colors as detailed later.

FIG. 2 is a schematic cross-sectional view of the light-emitting element 30 in the display device 1 in accordance with the embodiment. The display device 1 includes: an active substrate 20; the light-emitting elements 30 and a bank 25 both on the active substrate 20; and a sealing layer (not shown). Note that FIG. 2 shows only one of the plurality of light-emitting elements 30 in the display device 1.

The active substrate 20 includes: a base member 21; a plurality of thin film transistors (TFTs) 10 and various wiring both on the base member 21; and an insulating layer 22 provided on the base member 21 and covering various wiring. The base member 21 is made of, for example, a rigid material such as glass or made of a flexible material. Examples of flexible materials include resin materials such as PET (polyethylene terephthalate) and polyimide.

Each thin film transistor 10 is connected to an associated one of the light-emitting elements 30 and is a switching element for turning on and off the light-emitting element 30. The thin film transistor 10 includes, for example, a gate electrode, a gate insulating layer covering the gate electrode, a semiconductor layer on the gate insulating layer, and a source electrode and a drain electrode both on the semiconductor layer.

The gate electrode, the source electrode, and the drain electrode are made of, for example, a metal material such as copper or titanium. The gate insulating layer is made of, for example, an inorganic insulating material such as silicon oxide, silicon nitride, or silicon oxynitride. The semiconductor layer is made of, for example, IGZO (indium gallium zinc oxide), IZO (indium zinc oxide), GZO (gallium-doped zinc oxide), AZO (aluminum-doped zinc oxide), ZnO, In₂O₃, or Ga₂O₃.

The insulating layer 22 is disposed on the base member 21, covering the thin film transistors 10. The insulating layer 22 is made of, for example, an insulating resin material such as acrylic or polyimide. The insulating layer 22 may include an inorganic insulating layer. The inorganic insulating layer is made of, for example, an inorganic insulating material such as silicon oxide, silicon nitride, or silicon oxynitride.

The bank 25 and the light-emitting elements 30 are disposed on the active substrate 20. Each light-emitting element 30 is structured so as to be capable of emitting light of different colors, depending on the drive voltage applied thereto. The light-emitting element 30 is, for example, an OLED (organic light-emitting diode) element or a QLED (quantum-dot light-emitting diode) element containing a semiconductor nanoparticle material in a light-emitting layer.

Each pixel PX (FIG. 1) includes one ofthe light-emitting elements 30. The light-emitting element 30 includes, for example, an anode (first anode) 31, a hole transport layer 32, a light-emitting layer 33, an electron transport layer 34, and a cathode (first cathode) 35, which are stacked sequentially in this order when viewed from the active substrate 20. As an example, the anode 31, the hole transport layer 32, the light-emitting layer 33, and the electron transport layer 34 are provided in an insular manner for each light-emitting element 30. For instance, the cathode 35 is provided contiguously on the electron transport layer 34 and the bank 25 and commonly across the plurality of light-emitting elements 30.

The bank 25 covers, for example, an edge of the anode 31. The provision of the bank 25 between the adjacent light-emitting elements 30 restrains color mixing due to a leaking electric field between the adjacent light-emitting elements 30. In other words, the bank 25 serves as an element isolation layer that prevents color mixing between the adjacent light-emitting elements 30. The bank 25 is, for example, an organic insulating layer made of an organic material such as polyimide resin or acrylic resin.

The bank 25 is formed by, for example, forming the anodes 31 in an insular manner on the active substrate 20 by patterning, thereafter etching the hole transport layer 32, the light-emitting layer 33, and the electron transport layer 34 formed contiguously with the plurality of light-emitting elements 30, and filling the etched grooves with an organic material. Note that the bank 25 may be formed by any other method. In addition, the display device 1 does not necessarily include the bank 25.

The anode 31 is connected to the drain electrode of the thin film transistor 10 on the active substrate 20. A voltage is applied across the anode 31 in accordance with the light-emission luminance and the emission color of the light-emitting layer 33. The anode 31 is, for example, a reflective electrode that reflects visible light. The anode 31 has, for example, a layered structure including: a reflective layer of a metal material, such as aluminum, copper, gold, or silver, that has a high reflectance to visible light; and a transparent layer of a transparent material such as ITO, IZO, ZnO, AZO, BZO, or GZO. Note that the anode 31 may have a single-layer structure including a reflective layer.

The cathode 35 is fed with, for example, a reference voltage that is common to the plurality of light-emitting elements 30. The cathode 35 is, for example, a transparent electrode that transmits visible light. The cathode 35 contains, for example, ITO, IZO, ZnO, AZO, BZO, or GZO, which are all transparent materials.

Note that the present embodiment is described assuming that the cathode 35 is fed with the constant, reference voltage and that the anode 31 is fed with drive voltages (a resetting voltage, a setting voltage, and a light-emission voltage, which will be described later) for an image display by a power supply unit (first power supply unit) 50. A different set of drive voltages can be fed to each insular anode 31. It should be understood that this is not the only possible implementation of the present invention; alternatively, the cathode 35 may be fed with a drive voltage by the power supply unit 50, and the anode 31 may be fed with the constant, reference voltage.

The power supply unit 50, for example, supplies the reference voltage to the cathode 35 and supplies a drive voltage to the anode 31, on the basis of control instructions from a control unit 60. The provision of the reference voltage to the cathode 35 and the provision of a drive voltage to the anode 31, both by the control unit 60 and the power supply unit 50, enables the light-emitting element 30 to emit red light, green light, blue light, or mixed-color light of these colors with a desirable light-emission luminance. An image is hence displayed on the display area 5.

The present embodiment is described assuming also that the anode 31 is a reflective electrode and that the cathode 35 is a transparent electrode. Alternatively, the anode 31 may be a transparent electrode, and the cathode 35 may be a reflective electrode.

The hole transport layer 32 is disposed between the anode 31 and the light-emitting layer 33. The hole transport layer 32, for example, transports holes (electric charges) to the light-emitting layer 33. The hole transport layer 32 is made of, for example, tungsten oxide, nickel oxide, molybdenum oxide, or copper oxide.

The electron transport layer 34 is disposed between the cathode 35 and the light-emitting layer 33. The electron transport layer 34, for example, transports electrons to the light-emitting layer 33. The electron transport layer 34 is made of, for example, either a material containing at least one of species of ZnO, TiO₂, and InGaZnO (indium gallium zink oxide) or any one of these materials doped with at least one species of metal ions selected from Li, Na, K, Mg, and Ca.

There may be provided other layers such as a hole injection layer between the anode 31 and the hole transport layer 32. There may also be provided other layers such as an electron injection layer between the cathode 35 and the electron transport layer 34.

The light-emitting layer 33 is disposed between the anode 31 and the cathode 35. Specifically, in the present embodiment, the light-emitting layer 33 is disposed between the hole transport layer 32 and the electron transport layer 34. The light-emitting layer 33 emits visible light, for example, from the holes injected from the hole transport layer 32 and the electrons injected from the electron transport layer 34. For instance, the light-emitting layer 33 emits any of red light (light of a first color), green light (light of a second color, light of a first color), and blue light (light of a third color, light of a second color) or a mixture of light of these colors (e.g., white light).

The light-emitting layer 33 includes: a plurality of quantum dots (first quantum dots) 40R that are semiconductor nanoparticles that emit light of a first color; a plurality of quantum dots (second quantum dots, first quantum dots) 40G that are semiconductor nanoparticles that emit light of a second color having a shorter peak wavelength than the light of the first color; and a plurality of quantum dots (third quantum dots, second quantum dots) that are semiconductor nanoparticles that emit light of a third color having a shorter peak wavelength than the light of the first color and the light of the second color.

For instance, the quantum dots 40R emit red light, the quantum dots 40G emit green light, and the quantum dots 40B emit blue light.

Red light has a peak wavelength, for example, in a wavelength range of from 600 nm exclusive to 780 nm inclusive. Green light has a shorter peak wavelength than red light and has a peak wavelength, for example, in a wavelength range of from 500 nm exclusive to 600 nm inclusive. Blue light has a shorter peak wavelength than red light and green light and has a peak wavelength, for example, in a wavelength range of from 400 nm inclusive to 500 nm inclusive. Note that the quantum dots 40R, 40G, 40B in the light-emitting layer 33 do not necessarily emit red, green, and blue light respectively.

The quantum dots 40R, 40G. 40B in the light-emitting layer 33 emit light at different voltages. As an example, among the quantum dots 40R, 40G, 40B, the quantum dots 40R start emitting light at a lower voltage (emission-starting voltage) than do the quantum dots 40G, 40B. Also, as an example, the quantum dots 40G start emitting light at a lower voltage than do the quantum dots 40B.

Therefore, in the display device 1 in accordance with the present embodiment, the quantum dots 40R, 40G, 40B can emit either monochromatic, red, green, or blue light, which is light of different colors, or light of a mixed color, by supplying, to the light-emitting elements 30, a drive voltage that produces a voltage that suits the quantum dots 40R, 40G, 40B.

The light-emitting layer 33 is formed by coating using a mixed solution prepared by mixing and dispersing the quantum dots 40R, 40G, 40B in a dispersion medium such as toluene.

As an example, the quantum dots 40R have a so-called core-shell structure including a core (first core) 41R and a shell (first shell) 42R surrounding the core 41R. As an example, the quantum dots 40G have a so-called core-shell structure including a core (second core) 41G and a shell (second shell) 42G surrounding the core 41G. As an example, the quantum dots 40B have a so-called core-shell structure including a core (third core) 41B and a shell (third shell) 42B surrounding the core 41B.

Note that throughout the following description, the quantum dots 40R, 40G, 40B may be referred to simply as the quantum dots 40 when there is no need to distinguish between the quantum dots 40R, 40G, 40B, the cores 41R, 41G, 41B may be referred to simply as the cores 41 when there is no need to distinguish between the cores 41R, 41G, 41B, and the shells 42R, 42G, 42B may be referred to simply as the shells 42 when there is no need to distinguish between the shells 42R, 42G, 42B.

The cores 41R. 41G. 41B contain, for example, a material selected from the group consisting of CdS, CdSe, CdTe, ZnS, ZnSe, ZnTe, InN, InP, InAs, InSb, AlP, AlS, AlAs, AlSb, GaN, GaP, GaAs, GaSb, and combinations of any of these compounds.

The shells 42R, 42G contain a transition metal oxide. For instance, the shells 42R, 42G contain different transition metal oxides. Note that the shells 42R, 42G may have a single-layer structure or a multilayer structure with an outermost shell containing a transition metal oxide. Examples of the transition metal oxide contained in the shells 42R, 42G include TiO₂, ZrO₂, HfM₂, Nb₂O₅, Ta₂O₅, RuO₂, IrO₂, Fe₃O₄, ZnO, NiO, and complex oxides of any of these compounds.

The transition metal oxide contained in the shell 42R may be a material that has a greater band gap than the emission wavelength of the core 41R. Additionally, the transition metal oxide contained in the shell 42G may be a material that has a greater band gap than the emission wavelength of the core 41G.

Here, the use of a transition metal oxide such as ZnO in the shells 42R, 42G enables the shells 42R, 42G to serve as the shells of the quantum dots 40R, 40G that have a core-shell structure (e.g., a terminal for surface defect) and additionally allows for changing the resistance of the shells 42R, 42G as will be described later.

When the shells 42R, 42G have a single-layer structure, for example, the quantum dots 40R, 40G may have a core-shell structure with the cores 41R, 41G containing CdSe or InP and the shells 42R, 42G containing ZnO.

When the shells 42R, 42G have a multilayer structure, for example, the quantum dots 40R may have a so-called double-shell structure, for example, with the inner layer of the shell 42R being disposed around the core 41R and the outer layer (outermost shell) of the shell 42R being disposed around the inner layer. In addition, the quantum dots 40G may have a so-called double-shell structure, for example, with the inner layer of the shell 42G being disposed around the core 41G and the outer layer (outermost shell) of the shell 42G being disposed around the inner layer.

When the quantum dots 40R, 40G have a double-shell structure, the cores 41R, 42G, the inner layers of the shells 42R, 42G, and the outer layers of the shells 42R, 42G may contain different materials so that the cores 41R, 41G can contain ZnSCdSe or InP, the inner layers of the shells 42R, 42G can contain ZnS, and the outer layers (outermost shells) of the shells 42R, 42G can contain ZnO.

When the shells 42R, 42G have such a multilayer structure, the outer layers (outermost shells) of the shells 42R, 42G preferably contain a transition metal oxide (e.g., ZnO), and the inner layers of the outer layers (outermost shells) of the shells 42R, 42G preferably contain a material (e.g., ZnS) that has the same crystal structure (transition metal oxide with a sphalerite structure or a wurtzite structure) as the transition metal oxide (e.g., ZnO) contained in the outer layers (outermost shells). The quantum dots 40R, 40G can thus restrain crystal defects, thereby restraining decreases in luminous efficiency.

The shell 42B contains, for example, a transition metal compound, which may be, as an example, ZnS_{X}Se_{1-X} (0≤X≤1).

Since the shells 42R, 42G contain a transition metal oxide, the shells 42R, 42G change resistance from high to low when the shells 42R, 42G are fed with a particular voltage. This voltage at which resistance changes from high to low is referred to as the setting voltage. Once the shells 42R, 42G change resistance from high to low, electrons and holes become unlikely to be injected to the cores 41R, 41G, which in turn inhibits light-emission of the quantum dots 40R, 40G.

This particular mechanism, for example, when the light-emitting layer 33 emits blue light, can produce highly pure blue light by inhibiting light-emission of those quantum dots which should not emit light (e.g., the quantum dots 40R, 40G) among the quantum dots 40R, 40G, 40B in the light-emitting layer 33. Those quantum dots which should not emit light, other than those quantum dots which should emit light, among the quantum dots 40R, 40G, 40B can be selectively inhibited from emitting light in this manner. The light-emitting layer 33 can hence emit light of a desirable color with high purity.

This setting voltage varies depending on the metal element in the transition metal oxide, the thickness of the shell, and the crystal structure. The shells 42R, 42G therefore exhibit different setting voltages when the shells 42R, 42G are formed of transition metal oxides with different metal elements, shell thicknesses, and crystal structures. The quantum dots 40R, 40G can be hence selectively inhibited from emitting light. The light-emitting layer 33 can thus emit light of a desirable color with high purity.

The shells 42R and 42G can be made of materials that provide different setting voltages at which resistance changes from high to low. For instance, the shell 42G may be made of a material that provides a higher setting voltage at which resistance changes from high to low than the shell 42R. Alternatively, the shell 42R may be made of a material that provides a higher setting voltage at which resistance changes from high to low than the shell 42G.

For instance, when the quantum dots 40R, 40G, 40B in the light-emitting layer 33 are made of the same material, the quantum dots 40R have a greater average particle diameter than do the quantum dots 40G, and the quantum dots 40G have a greater average particle diameter than do the quantum dots 40B.

Note that the light-emitting element 30 does not necessarily have the above-described stacking order. As an example, the light-emitting element 30 may include the cathode 35, the electron transport layer 34, the light-emitting layer 33, the hole transport layer 32, and the anode 31 in this order when viewed from the active substrate 20. As another example, the anode 31 may be a transparent electrode, and the cathode 35 be a reflective electrode.

As described here, in the display device 1 in accordance with the present embodiment, the light-emitting layer 33 of the light-emitting element 30 includes: the quantum dots 40R that emit red light (light of the first color); the quantum dots 40G that emit green light (light of the second color), which has a shorter peak wavelength than red light; and the quantum dots 40B with a shorter peak wavelength than green light. The quantum dots 40R, 40G, 40B emit light in accordance with the light-emission voltage fed from the power supply unit 50.

The shells 42R, 42G of the quantum dots 40R, 40G contain a transition metal compound. This particular composition enables controlling the resistance of the shells 42R, 42G of the quantum dots 40R, 40G from high to low, which in turn enables selectively controlling emission and non-emission of the quantum dots 40R, 40G.

The light-emitting element 30 can hence emit light of a desirable color with high purity when compared with a light-emitting element including a light-emitting layer of quantum dots containing no transition metal compound in the shells thereof.

In addition, since in the display device 1, the light-emitting layers 33 of the adjacent light-emitting elements 30 contain the same material, there is no need to perform patterning on the three light-emitting layers that emit light of different colors to generate red light, green light, and blue light.

In other words, since in the display device 1 including the plurality of light-emitting elements 30 in accordance with the present embodiment, the light-emitting layers 33 of the adjacent light-emitting elements 30 contain the same light-emitting material, there is no need to use a different material to form the light-emitting layer 33 of each light-emitting element 30. Therefore, the manufacturing steps can be reduced when compared with cases where the light-emitting layers are formed of different materials for emission of different colors. As a result, the manufacturing cost of the display device 1 can be reduced.

As described here, in the display device 1 in accordance with the present embodiment, the light-emitting layers 33 of each pair of adjacent light-emitting elements 30 contain the same light-emitting material. Therefore, the light-emitting layers 33 are not necessarily formed by insular patterning for each light-emitting element 30 and may be provided as a contiguous layer that is common to the light-emitting elements 30.

Additionally, the hole transport layers 32 and the electron transport layers 34 are not necessarily formed by insular patterning for each light-emitting element 30 and may be provided as a contiguous layer that is common to the light-emitting elements 30.

In the present embodiment, the light-emitting layer 33 is described as including: the quantum dots 40R that emit red light (light of the first color); the quantum dots 40G that emit green light (light of the second color), which has a shorter peak wavelength than red light; and the quantum dots 40B with a shorter peak wavelength than green light. The light-emitting layer 33 may alternatively contain quantum dots that emit light of any two of the colors. In such a case, the quantum dots that emit light of the single remaining color may be contained in the light-emitting layer of a light-emitting element adjacent to the light-emitting element 30 including the light-emitting layer 33.

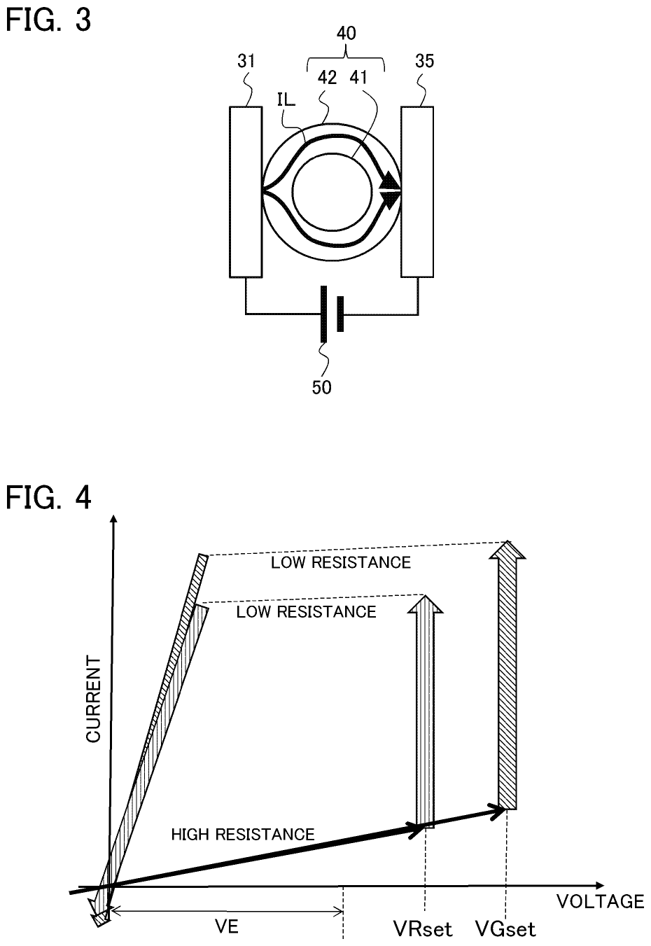

FIG. 3 is a schematic diagram illustrating a leak current IL flowing in the shell 42 of the quantum dot 40 in accordance with the embodiment.

Referring to FIG. 3, as a setting voltage is fed to the quantum dot 40 containing a transition metal oxide in the shell 42, the shell 42 changes from high resistance to low resistance, allowing the leak current IL to flow in the shell 42. This flow of the leak current IL in the shell 42 renders the core 41 surrounded by the shell 42 unlikely to be injected with carriers (electrons and holes).

FIG. 4 is a schematic diagram representing a relationship between voltage and current supplied to the quantum dots 40R, 40G in accordance with the embodiment. For instance, in FIG. 4, the horizontal axis represents the voltage fed to the quantum dots 40R, 40G, and the vertical axis represents the current that flows in the shells 42R of the quantum dots 40R and the shells 42G of the quantum dots 40G.

For instance, as a setting voltage VRset for the shells 42R is fed to the shells 42R, the shells 42R abruptly change from high resistance to low resistance, thereby abruptly increasing the current (leak current IL) in the shells 42R. This renders the cores 41R surrounded by the shells 42R in the quantum dots 40R unlikely to be injected with electrons and holes. As a result, the quantum dots 40R become unlikely to emit red light, thereby rendering, for example, the light-emitting layer 33 capable of emitting light of a desirable color, for example, green light or blue light, with high purity.

In addition, for example, as a setting voltage VGset for the shells 42G is fed to the shells 42G, the shells 42G abruptly change from high resistance to low resistance, thereby abruptly increasing the current (leak current IL) in the shells 42G. This renders the cores 41G surrounded by the shells 42G in the quantum dots 40G unlikely to be injected with electrons and holes. As a result, the quantum dots 40G become unlikely to emit green light, thereby rendering, for example, the light-emitting layer 33 capable of emitting light of a desirable color, for example, blue light, with high purity.

The setting voltages VRset, VGset are higher than a light-emission voltage VE fed to the light-emitting elements 30 to cause the light-emitting elements 30 to emit light. Therefore, for example, the quantum dots 40R can be inhibited from emitting light, and the quantum dots 40G, 40B be controlled in terms of the light-emission luminance thereof, to display an image, by feeding the setting voltage VRset to the light-emitting elements 30 before feeding the light-emission voltage VE. In addition, for example, the quantum dots 40R, 40G can be inhibited from emitting light, and the quantum dots 40B be controlled in terms of the light-emission luminance thereof, to display an image, by feeding the setting voltage VGset to the light-emitting elements 30 before feeding the light-emission voltage VE.

These setting voltages vary depending on the metal element in the transition metal oxide. The quantum dots 40R, 40G have different setting voltages due to the shells 42R, 42G containing different metal elements in the transition metal oxides thereof.

Furthermore, the setting voltages vary depending also on the thickness of the shell. As the shell becomes thicker, the shell increases the resistance thereof, and hence the setting voltage thereof. This enables increasing the distance by which adjacent cores are separated, thereby enabling improving the luminous efficiency of the quantum dots when compared with thin shells. Meanwhile, as the shell becomes thinner, the shell decreases the resistance thereof, and hence the setting voltage thereof, which decreases the luminous efficiency of the quantum dots due to proximity effect when compared with thick shells.

As shown in FIG. 4, when the setting voltage VGset is higher than the setting voltage VRset, the setting voltage VRset can be decreased, as well as the thickness of the shell 42G can be increased. Therefore, the luminous efficiency of the quantum dots 40G can be improved when compared with cases where the shells 42G are thin.

On the other hand, when the setting voltage VRset is higher than the setting voltage VGset, the setting voltage VGset can be decreased, as well as the thickness of the shell 42R can be increased. Therefore, the luminous efficiency of the quantum dots 40R can be improved when compared with cases where the shells 42R are thin.

If the shell is too thin, the shell may decrease the resistance thereof excessively, and the supply of the setting voltage could not induce a clear-cut change from high resistance to low resistance, failing to inhibiting light-emission. If the shell is too thick, disadvantages also follow, where the shell increases the resistance thereof excessively, and the core surrounded by the shell is unlikely to be injected with electrons and holes, which renders the quantum dot unlikely to emit light.

In view of this, at least either the shell 42R or the shell 42G preferably has a thickness of from 1 nm to 50 nm both inclusive. The shell thickness of greater than or equal to 1 nm enables the supply of the setting voltage to induce a clear-cut change from high resistance to low resistance even in thin shells, which enables controlling emission and non-emission of the quantum dots. Meanwhile, the shell thickness of less than or equal to 50 nm enables the injection of electrons and holes to the cores, thereby allowing the quantum dots to emit light, even when the shell exhibits an increased resistance.

Furthermore, at least either the shell 42R or the shell 42G more preferably has a thickness of from 5 nm to 20 nm both inclusive. The shell thickness of greater than or equal to 5 nm induces a more clear-cut change from high resistance to low resistance in the shells, which enables controlling emission and non-emission of the quantum dots. Meanwhile, the shell thickness of less than or equal to 20 nm more readily enables the injection of electrons and holes to the cores, thereby allowing the quantum dots to more efficiently emit light.

When the shells 42R, 42G have a multilayer structure, the inner layer of the outermost shell in the shells 42R, 42G preferably contains a material that has the same crystal structure (transition metal oxide with a sphalerite structure or a wurtzite structure) as the transition metal oxide contained in the outermost shell. This configuration can restrain crystal defects and decreasing luminous efficiency when compared with cases where the layer containing a transition metal oxide has a different crystal structure from either the core or the inner layer of that layer.

Note that the transition metal oxide contained in the shells 42R, 42G is, for example, ZnO, and the material that has the same crystal structure as the transition metal oxide contained in the shells 42R, 42G is, for example, ZnS.

The core 41B and the shell 42B preferably contain a transition metal compound. The transition metal compound is, for example, ZnS_{X}Se_{1-X} (0≤X≤1). This leads to strong quantum confinement due to a wide band gap, thereby improving the luminous efficiency of the quantum dots 40B.

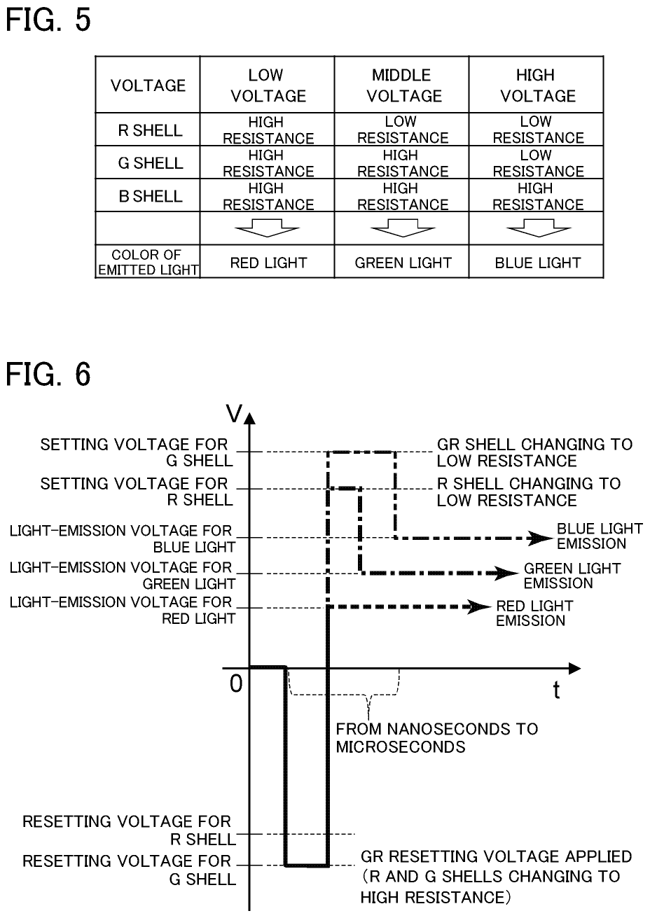

FIG. 5 is a diagram representing voltages fed to the quantum dots 40R, 40G, 40B and resistance conditions of the shells 42R, 42G, 42B in accordance with the embodiment. Note that in the drawing, “R shell” indicates the shell 42R, “G shell” indicates the shell 42G, and “B shell” indicates the shell 42B.

As described above, the power supply unit 50 can control the color of the emission of the light-emitting elements 30 including the light-emitting layers 33 containing the quantum dots 40R, 40G, 40B by controlling the resistance conditions of the shells 42R, 42G, 42B of the quantum dots 40R, 40G, 40B respectively.

The description here assumes that the light-emission voltage is higher for the quantum dots 40G and even higher for the quantum dots 40B than for the quantum dots 40R. The light-emission voltage for the quantum dots 40R is referred to as the “low voltage,” the light-emission voltage for the quantum dots 40G as the “middle voltage,” and the light-emission voltage for the quantum dots 40B as the “high voltage.”

The description here assumes also that the setting voltage is higher for the shell 42G than for the shell 42R.

For instance, when the shells 42R, 42G, 42B of the quantum dots 40R, 40G, 40B are in the high voltage state, the shells 42R, 42G, 42B work as normal shells because the transition metal oxide has a wide gap.

As the power supply unit 50 feeds the low voltage to the light-emitting elements 30, only the quantum dots 40R emit light among the quantum dots 40R, 40G, 40B. The quantum dots 40G, 40B, being fed with a voltage lower than the light-emission voltage, do not emit light. Hence, the light-emitting layer 33 can emit red light.

In addition, for example, to cause green emission, the power supply unit 50 feeds the setting voltage for the shell 42R to the light-emitting element 30 in advance before causing green emission, thereby causing the shell 42R, among the shells 42R, 42G, 42B, to change from high resistance to low resistance. The power supply unit 50 then feeds the middle voltage to the light-emitting element 30. Hence, among the quantum dots 40R, 40G, 40B, the quantum dots 40R are inhibited from emitting light because a leak current flows in the shell 42R, rendering the core 41R unlikely to be injected with electrons and holes. The quantum dots 40B do not emit light due to a voltage lower than the light-emission voltage, and only the quantum dots 40G emit green light. Hence, the light-emitting layer 33 emits only green light.

In addition, for example, to cause blue emission, the power supply unit 50 feeds the setting voltage for the shell 42G (in other words, the higher of the setting voltages for the shells 42R, 42G) to the light-emitting element 30 in advance before causing blue emission, thereby causing the shells 42R, 42G, among the shells 42R, 42G, 42B, to change from high resistance to low resistance. The power supply unit 50 then feeds the high voltage to the light-emitting element 30. Hence, among the quantum dots 40R, 40G. 40B, the quantum dots 40R. 40G are inhibited from emitting light because a leak current flows in the shells 42R, 42G, rendering the cores 41R, 41G unlikely to be injected with electrons and holes. Only the quantum dots 40B emit blue light. Hence, the light-emitting layer 33 emits only blue light.

FIG. 6 is a diagram representing changes over time in the voltage fed to the quantum dots 40R, 40G, 40B in accordance with the embodiment. The power supply unit 50 may feed the resetting voltage to the light-emitting elements 30 on the basis of instructions from the control unit 60 before causing the quantum dots 40R, 40G, 40B to emit light, to more reliably changing the shells 42R, 42G, 42B to high resistance.

For instance, before feeding the light-emission voltage for red light, green light, and blue light to the light-emitting elements 30, the power supply unit 50 feeds, to the light-emitting element 30, in other words, to the anode 31 or the cathode 35, a resetting voltage V that has a different polarity from the light-emission voltage and that changes the shells 42R, 42G to high resistance.

The power supply unit 50 feeds, to the light-emitting element 30, in other words, to the anode 31 or the cathode 35, a lower of the resetting voltage for the shell 42R and the resetting voltage for the shell 42G. As an example, it is assumed that the resetting voltage is lower for the shell 42G than for the shell 42R.

Thereafter, to cause red emission, the power supply unit 50 feeds the light-emission voltage for the quantum dots 40R to the light-emitting element 30, in other words, to the anode 31 or the cathode 35. Hence, red light is emitted.

Alternatively, to cause green emission, the power supply unit 50 feeds the setting voltage for the shell 42R to the light-emitting element 30, in other words, to the anode 31 or the cathode 35, thereby changing the shell 42R from high resistance to low resistance, before feeding the light-emission voltage for the quantum dots 40G. Hence, green light is emitted.

Alternatively, to cause blue emission, the power supply unit 50 feeds the setting voltage for the shell 42G (the higher of the setting voltage for the shell 42R and the setting voltage for the shell 42G) to the light-emitting element 30, in other words, to the anode 31 or the cathode 35, thereby changing the shells 42R, 42G from high resistance to low resistance, before feeding the light-emission voltage for the quantum dots 40B. Hence, blue light is emitted.

Note that the time from the moment the power supply unit 50 starts feeding the resetting voltage to the moment the power supply unit 50 terminates feeding the setting voltage is until the current value in the light-emitting element 30 reaches a prescribed value or a predetermined time and is, for example, nanoseconds or microseconds.

For instance, for the shells 42R, 42G, the setting voltage may be from 5 volts to 12 volts both inclusive, the resetting voltage be from −10 volts to 0 volts both inclusive, the minimum light-emission voltage for red light be 2.0 volts, the minimum light-emission voltage for green light be 2.2 volts, and the minimum light-emission voltage for blue light be 2.8 volts.

In addition, the power supply unit 50 used is preferably capable of applying such a relatively high voltage that the light-emitting elements 30 in accordance with the present embodiment have a higher setting voltage than a light-emission voltage. However, the setting voltage is preferably less than or equal to 12 volts because the setting voltage needs to be in the range of voltages that can be generated by the power supply circuit used in the display device 1. Hence, the power supply unit 50 can include a power supply circuit that has high general applicability.

In addition, for example, the light-emitting elements 30 are capable of a light-emission luminance of, for example, from 300 to 1000 cd/m² at approximately 5 volts and sufficiently allow the display device 1 to function as a display device. Therefore, the power supply unit 50 can include a power supply circuit that has high general applicability, by specifying the setting voltage to be greater than or equal to 5 volts.

The minimum light-emission voltages for red light, green light, and blue light are, for example, approximately equal respectively to the energy levels of the emission wavelengths thereof. As an example, the minimum light-emission voltage for red light may be 2.0 volts, the minimum light-emission voltage for green light be 2.2 volts, and the minimum light-emission voltage for blue light be 2.8 volts.

In addition, the resetting voltage has the opposite polarity from the light-emission voltage and receives the opposite bias. In view of this, by specifying the range of the resetting voltage to a maximum of 0 volts or less and a minimum of −12 volts or greater, the resetting voltage can be sufficiently reduced to a range the light-emitting elements 30 can withstand reverse bias.

Note that the above-described voltages are mere examples. The setting voltage, the resetting voltage, and the light-emission voltage for each color are not necessarily limited to the above-described numerical values.

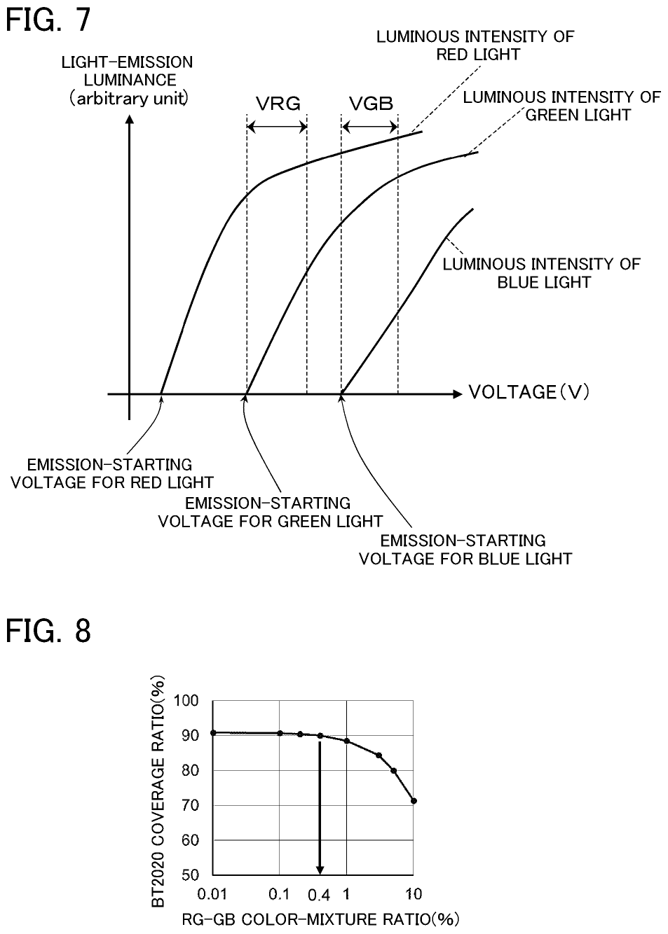

A description is given next of a relationship between the voltage fed to the light-emitting element 30 and the color of emission of the light-emitting element 30 with reference to FIGS. 7 to 9.

FIG. 7 is a diagram representing a relationship between the voltage applied to the light-emitting element 30 and the luminous intensity of the light-emitting element 30 in accordance with the embodiment. In the graph in FIG. 7, the horizontal axis represents the voltage fed to the light-emitting element 30, and the vertical axis represents the light-emission luminances of the quantum dots 40R, 40G, 40B contained in the light-emitting layer 33.

Referring to FIG. 7, as the voltage fed to the light-emitting element 30, in other words, to the anode 31 or the cathode 35, is increased, the quantum dots 40R start emitting red light at the emission-starting voltage for the quantum dots 40R, the quantum dots 40G then start emitting green light at the emission-starting voltage for the quantum dots 40G, and the quantum dots 40B thereafter start emitting blue light at the emission-starting voltage for the quantum dots 40B.

In this situation, in a voltage range VRG shown in FIG. 7, green light can gradually appear mixing with red light that has a higher light-emission luminance because the quantum dots 40G start emitting green light while the quantum dots 40R are emitting red light. In addition, in a voltage range VGB shown in FIG. 7, blue light can gradually appear mixing with green light that has a higher light-emission luminance because the quantum dots 40B start emitting blue light while the quantum dots 40G are emitting green light.

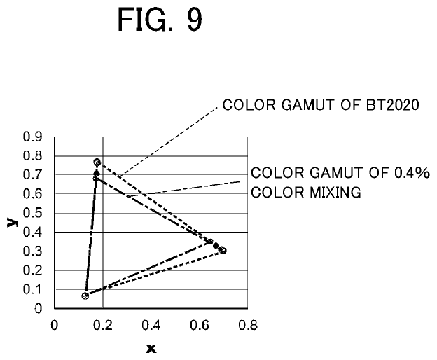

FIG. 8 is a diagram representing a relationship between a color-mixture ratio of red and green light, a color-mixture ratio of green and blue light, and a BT2020 coverage ratio in accordance with the embodiment. FIG. 9 is a diagram illustrating the BT2020 coverage ratio in accordance with the embodiment. In FIG. 9, the broken-line triangle represents the BT2020 color gamut. In FIG. 9, the dash-dot-line triangle represents the color gamut where the color-mixture ratio of green light in red light and the color-mixture ratio of blue light in green light are 0.4% in terms of energy ratio.

Referring to FIG. 8, for example, the range of voltage fed to the light-emitting element 30 is preferably controlled so that the color-mixture ratio of green light in red light and the color-mixture ratio of blue light in green light are within 0.4% in terms of energy ratio. The range of the drive voltage applied to the light-emitting layer 33 is preferably so controlled that green light is 97 cd/m² for 100 cd/m² of red light (G/R=0.97) and that blue light is 0.3 cd/m² for 100 cd/m^{2 of green light (B/G=}0.003), both when converted into a luminance ratio (calculated in terms of peak visual recognizability).

Hence, as shown in FIGS. 8 and 9, the light-emitting element 30 can emit light with a color gamut covering 90% or more of the BT2020 color gamut. In other words, the resultant light-emitting element 30 emits light with a wide color gamut.

In addition, the power supply unit 50 preferably feeds, to the anode 31 or the cathode 35, the light-emission voltage for red emission with a maximum voltage at which the luminous energy of green light is less than or equal to 5.0% of the luminous energy of red light. Hence, 80% or more of BT2020 is covered.

The power supply unit 50 preferably feeds, to the anode 31 or the cathode 35, the light-emission voltage for green light emission with a maximum voltage at which the luminous energy of blue light is less than or equal to 5.0% of the luminous energy of green light. Hence, 80% or more of BT2020 is covered.

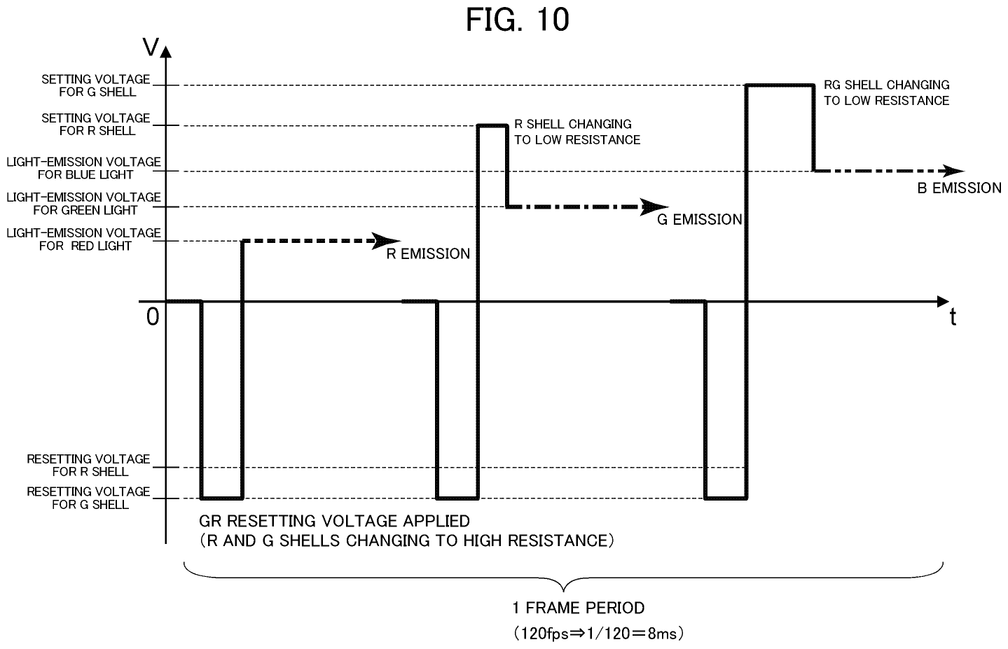

FIG. 10 is a diagram representing an example of driving the light-emitting elements 30 by a field sequential technique in accordance with Variation Example 1 of the embodiment. The rate of the shells 42R, 42G changing from high resistance to low resistance is sufficiently higher than a human eye can recognize. Accordingly, the power supply unit 50 and the control unit 60 may drive the light-emitting elements 30 by a field sequential technique (color time division scheme).

Assume, as an example, that the power supply unit 50 and the control unit 60 control the display of images on the display device 1 at a frame rate of 120 Hz (1 frame period is equal to approximately 8 ms).

The power supply unit 50, for example, first, feeds, to the light-emitting elements 30, in other words, to the anodes 31 or the cathode 35, a lower of the resetting voltage for the shell 42R and the resetting voltage for the shell 42G. Next, the power supply unit 50 feeds the light-emission voltage for the quantum dots 40R to the light-emitting elements 30, in other words, to the anodes 31 or the cathode 35. Next, the power supply unit 50 feeds to the light-emitting elements 30, in other words, to the anodes 31 or the cathode 35, a lower of the resetting voltage for the shell 42R and the resetting voltage for the shell 42G. Next, the power supply unit 50 feeds the light-emission voltage for the quantum dots 40G to the light-emitting elements 30, in other words, to the anodes 31 or the cathode 35. Next, the power supply unit 50 feeds, to the light-emitting elements 30, in other words, to the anodes 31 or the cathode 35, a lower of the resetting voltage for the shell 42R and the resetting voltage for the shell 42G. Next, the power supply unit 50 feeds the light-emission voltage for the quantum dots 40B to the light-emitting elements 30, in other words, to the anodes 31 or the cathode 35.

The operation from the feeding of the first resetting voltage through the feeding of the light-emission voltage for the quantum dots 40B is performed in one frame period. This technique also allows the light-emitting elements 30 to emit red light, green light, and blue light, thereby enabling a display of various images on the display device 1.

Note that the order of colors of light emitted in one frame period is not necessarily red, green, and blue and may be changed in any given manner.

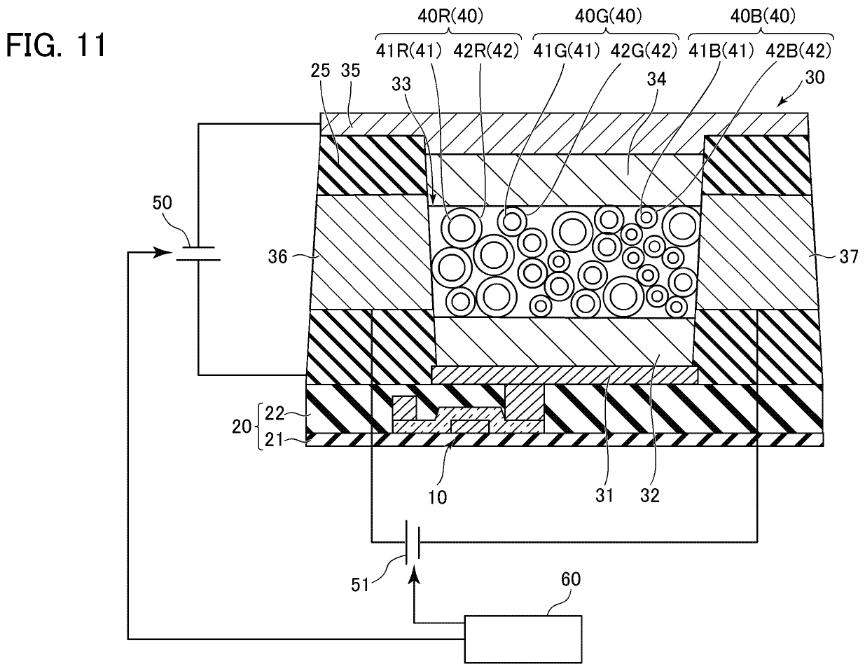

FIG. 11 is a schematic cross-sectional view of the light-emitting element 30 in the display device 1 in accordance with Variation Example 2 of the embodiment.

The light-emitting element 30 may further include an anode 36 (second anode) and a cathode (second cathode) 37 to restrain the degradation of the hole transport layer 32 and the electron transport layer 34 caused by the setting voltage and the resetting voltage being fed to the hole transport layer 32 and the electron transport layer 34. The display device 1 then may further include a power supply unit (second power supply unit) 51.

The anode 36 and the cathode 37 are disposed opposite each other across the light-emitting layer 33 in a plan view. In other words, the anode 36 and the cathode 37 are arranged in a direction perpendicular to the stack direction in which the anodes 31 and the cathode 35 are arranged. The anode 36 and the cathode 37 may, for example, be embedded in the bank 25.

The power supply unit 51 feeds a constant reference voltage to the cathode 37 and a setting voltage and a resetting voltage to the anode 36, all on the basis of control instructions from the control unit 60.

In the light-emitting element 30 shown in FIG. 11, the setting voltage and the resetting voltage are not fed to the anode 31 or the cathode 35 by the power supply unit 50, but fed to the anode 36 or the cathode 37 by the power supply unit 51 provided separately from the power supply unit 50.

In other words, the power supply unit 51 feeds the setting voltage at which the shell 42R changes from high resistance to low resistance to the anode 36 or the cathode 37 before the power supply unit 50 feeds the light-emission voltage for green emission to the anode 31 or the cathode 35. In addition, the power supply unit 51 feeds the setting voltage at which the shell 42G changes from high resistance to low resistance to the anode 36 or the cathode 37 before the power supply unit 50 feeds the light-emission voltage for blue emission to the anode 31 or the cathode 35.

Hence, the supply of the setting voltage to the hole transport layer 32 and the electron transport layer 34 can be restrained, thereby restraining degradation of the hole transport layer 32 and the electron transport layer 34.

In addition, the power supply unit 51 feeds a resetting voltage that has a different polarity from the light-emission voltage (the light-emission voltage for any of the quantum dots 40R, 40G, 40B) and at which the shell 42R and the shell 42G are changed to high resistance to the anode 36 or the cathode 37 before the power supply unit 50 feeds the light-emission voltage (the light-emission voltage for any of the quantum dots 40R, 40G, 40B) to the anode 31 or the cathode 35.

Hence, the resetting voltage is restrained from being fed to the hole transport layer 32 and the electron transport layer 34, thereby restraining degradation of the hole transport layer 32 and the electron transport layer 34.

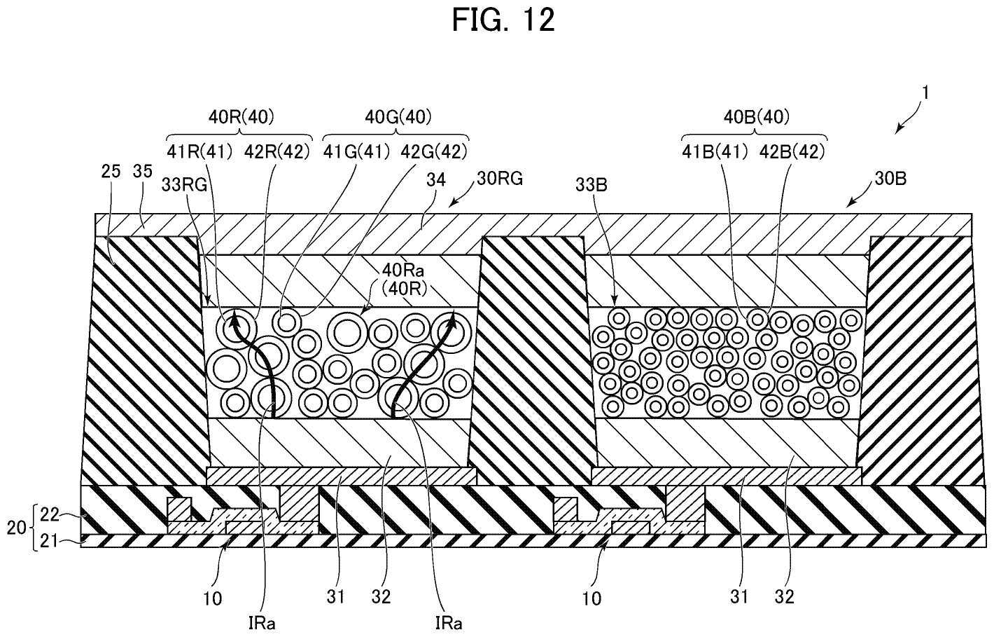

FIG. 12 is a schematic cross-sectional view of light-emitting elements 30RG, 30B in the display device 1 in accordance with Variation Example 3 of the embodiment.

The display device 1 may include: the light-emitting elements 30RG capable of emitting light of two colors; and the light-emitting elements 30B capable of emitting light of a single color, in place of the light-emitting elements 30. Adjacent pixels PX each include a light-emitting element 30RG and a light-emitting element 30B (FIG. 1).

The light-emitting element 30RG includes a light-emitting layer 33RG in place of the light-emitting layer 33 of the light-emitting element 30. The light-emitting element 30B includes a light-emitting layer 33B in place of the light-emitting layer 33 of the light-emitting element 30. The light-emitting elements 30RG, 30B have otherwise the same structure as the light-emitting element 30.

The light-emitting layer 33RG contains those of the quantum dots 40R, 40G, 40B which emit any two different types of light, for example, the quantum dots 40R, 40G. Hence, the light-emitting layer 33RG emits the red light emitted by the quantum dots 40R, the green light emitted by the quantum dots 40G, and light that is a mixture of these red light and green light.

The light-emitting layer 33B contains those of the quantum dots 40R, 40G, 40B which differ from the quantum dots of the type contained in the light-emitting layer 33RG, for example, the quantum dots 40B. Hence, the light-emitting layer 33B emits the blue light emitted by the quantum dots 40B.

Here, as the setting voltage and the resetting voltage are fed to the light-emitting element, only those quantum dots which are in a region where there are adjacent quantum dots that emit light of the same color change resistance of the shells in the light-emitting layer. In other words, when the setting voltage is fed, a current path forms between the electrodes through the quantum dots. Only the shells of the quantum dots that are in the current path change resistance, and the shells of the quantum dots that are not in the current path do not change resistance.

Therefore, in causing emission of the quantum dots (e.g., the blue light-emitting quantum dots 40B) that emit light at a higher voltage than the quantum dots (e.g., the red light-emitting quantum dots 40R) that have not changed resistance, the quantum dots (e.g., the red light-emitting quantum dots 40R) that have not changed resistance may also emit light, thereby lowering the purity of the color of the emitted light. This could reduce the BT2020 coverage ratio.

Accordingly, as shown in FIG. 12, the light-emitting layer 33RG containing the quantum dots 40R and the quantum dots 40G is provided in a different layer from the light-emitting layer 33B containing the quantum dots 40B.

Hence, for example, those adjacent, adjoining quantum dots 40R through which a current path IRa flows when the setting voltage or the resetting voltage for the shell 42R is fed can be increased in number in the light-emitting layer 33RG. Then, of the quantum dots 40R, the quantum dots 40Ra that are not in the path where the current path IRa flows and that are not adjacent to, and are therefore isolated from, the other quantum dots 40R can be reduced in number. In other words, the number of the quantum dots 40Ra that do not change the resistance of the shell 42R even when the setting voltage and the resetting voltage for the shell 42R are fed can be reduced. Hence, for example, since the number of the red light-emitting quantum dots 40Ra is reduced when the light-emission voltage for green emission is fed, green light can be produced with higher purity.

In addition, since the light-emitting layer 33B contains only the quantum dots 40B among the quantum dots 40R, 40G, 40B, red light and green light can be prevented from mixing with blue light. Therefore, the light-emitting layer 33B is capable of emit blue light with higher purity.

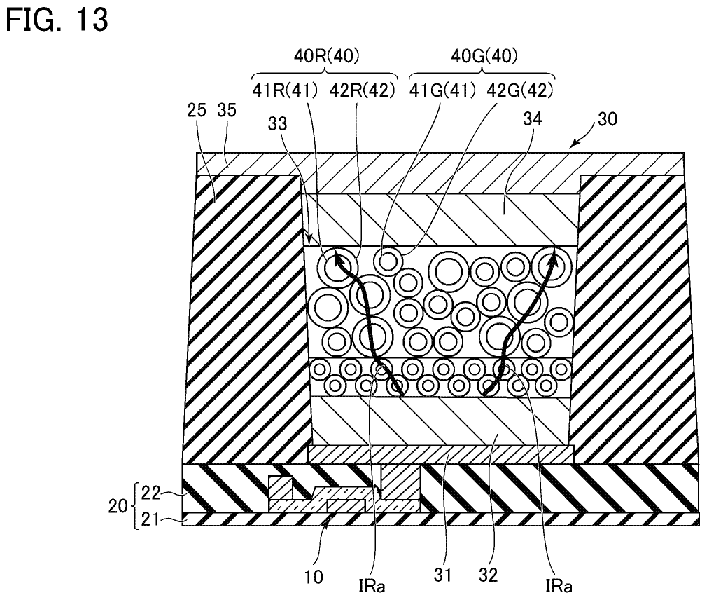

FIG. 13 is a schematic cross-sectional view of a light-emitting element 30 in the display device 1 in accordance with Variation Example 4 of the embodiment. Similarly to the light-emitting layer 33 of the light-emitting element 30 shown in FIG. 13, the light-emitting layer 33 may have a multilayer structure including a light-emitting layer 33B and a light-emitting layer 33RG. This structure also allows the number of the isolated quantum dots 40Ra to be reduced in the light-emitting layer 33RG, thereby producing green light with high purity. In addition, the light-emitting layer 33B is capable of emitting blue light with high purity.

The stacking order of the light-emitting layer 33RG and the light-emitting layer 33B is not limited in any particular manner. The light-emitting layer 33RG may be disposed close to the cathode 35, and the light-emitting layer 33B close to the anode 31, as shown in FIG. 13. As another alternative, the stacking order may be reversed, where the light-emitting layer 33RG is disposed close to the anode 31, and the light-emitting layer 33B close to the cathode 35.

Note that since the setting voltage and the resetting voltage are greater in absolute value than the light-emission voltage, the quantum dots 40B are also included in the path for the current path in the light-emitting layer 33B. However, since the shell 42B is not a transition metal oxide, there are no changes in the resistance. Additionally, since the resistance changes in a very short time of approximately from nanoseconds to microseconds, the light emitted during the resistance change hardly affects color mixing.

Any of the elements described in the embodiments and variation examples may be used in a proper combination so long as the combination works out well.

### REFERENCE SIGNS LIST

1 Display Device
30, 30RG, 30B Light-emitting Element
30R, 30G, 30B Quantum Dot
31 Anode (First Anode)
32 Hole Transport Layer
33, 33RG, 33B Light-emitting Layer
34 Electron Transport Layer
35 Cathode
36 Anode
37 Cathode
40, 40R, 40G, 40B Quantum Dot
41, 41R, 41G, 41B Core
42, 42R, 42G, 42B Shell
50 Power Supply Unit
51 Power Supply Unit
PX Pixel

1. A light-emitting element comprising:
a first anode;
a first cathode; and
a light-emitting layer between the first anode and the first cathode, the light-emitting layer containing a first quantum dot that emits light of a first color, wherein
the first quantum dot includes: a first core; and a first shell around the first core, the first shell containing a transition metal oxide, wherein
the light-emitting layer contains a second quantum dot that emits light of a second color having a shorter peak wavelength than does the light of the first color, the second quantum dot including: a second core; and a second shell around the second core, the second shell containing a transition metal oxide.

2. (canceled)

3. The light-emitting element according to claim 1, wherein the second shell contains a material that exhibits a higher setting voltage than does the first shell, the material changing from high resistance to low resistance at the setting voltage.

4. The light-emitting element according to claim 1, wherein the first shell contains a material that exhibits a higher setting voltage than does the second shell, the material changing from high resistance to low resistance at the setting voltage.

5. The light-emitting element according to claim 1, wherein at least either one of the first shell and the second shell has a thickness of from 1 nm to 50 nm both inclusive.

6. The light-emitting element according to claim 1, wherein the second shell has a multilayer structure including an outermost shell containing the transition metal oxide.

7. The light-emitting element according to claim 1, wherein the first shell has a multilayer structure including an outermost shell containing the transition metal oxide.

8. (canceled)

9. The light-emitting element according to claim 1, wherein the transition metal oxide is ZnO.

10. (canceled)

11. The light-emitting element according to claim 1, wherein the first quantum dot starts emitting light at a lower voltage than does the second quantum dot.

12. The light-emitting element according to claim 1, wherein the light-emitting layer contains a third quantum dot that emits light of a third color having a shorter peak wavelength than does the light of the second color, the third quantum dot including: a third core; and a third shell around the third core, the third shell containing a transition metal compound.

13. The light-emitting element according to claim 12, wherein the third shell contains ZnS_{X}Se_{1-X} (0≤X≤1).

14. The light-emitting element according to claim 12, wherein the second quantum dot starts emitting light at a lower voltage than does the third quantum dot.

15. A light-emitting device comprising:
the light-emitting element according to claim 1; and
a first power supply unit configured to feed, to either the first anode or the first cathode, a light-emission voltage that is in accordance with a luminance of either of the light of the first color and the light of the second color that is to be emitted.

16. The light-emitting device according to claim 15, wherein the first power supply unit, before feeding a light-emission voltage that causes the light of the second color to be emitted, feeds, to either the first anode or the first cathode, a setting voltage at which the first shell changes from high resistance to low resistance.

17. The light-emitting device according to claim 12, wherein the first power supply unit, before feeding the light-emission voltage to either the first anode or the first cathode, feeds, to either the first anode or the first cathode, a resetting voltage that has a different polarity from the light-emission voltage and at which the first shell changes to high resistance.

18. A light-emitting device comprising:
the light-emitting element according to claim 12 and
a first power supply unit configured to feed, to either the first anode or the first cathode, a light-emission voltage that is in accordance with a luminance of any of the light of the first color, the light of the second color, and the light of the third color that is to be emitted.

19. The light-emitting device according to claim 18, wherein the first power supply unit, before feeding a light-emission voltage that causes the light of the third color to be emitted, feeds, to either the first anode or the first cathode, a setting voltage at which both the first shell and the second shell change from high resistance to low resistance.

20. The light-emitting device according to claim 18, wherein the first power supply unit, before feeding the light-emission voltage to either the first anode or the first cathode, feeds, to either the first anode or the first cathode, a resetting voltage that has a different polarity from the light-emission voltage and at which the first shell and the second shell change to high resistance.

21. The light-emitting device according to claim 18, wherein
the first anode, the light-emitting layer, and the first cathode are sequentially stacked, and
the light-emitting device further comprises:
a second anode and a second cathode opposite each other across the light-emitting layer in a plan view; and
a second power supply unit configured to feed a voltage to the second anode and the second cathode.

22. The light-emitting device according to claim 21, wherein the second power supply unit:
before a light-emission voltage that causes the light of the second color to be emitted is fed to either the first anode or the first cathode, feeds, to either the second anode or the second cathode, a setting voltage at which the first shell changes from high resistance to low resistance; and
before a light-emission voltage that causes the light of the third color to be emitted is fed to either the first anode or the first cathode, feeds, to either the second anode or the second cathode, a setting voltage at which the second shell changes from high resistance to low resistance.

23. The light-emitting device according to claim 21, wherein the second power supply unit, before the light-emission voltage is fed to either the first anode or the first cathode, feeds, to either the second anode or the second cathode, a resetting voltage that has a different polarity from the light-emission voltage and at which the first shell and the second shell change to high resistance.

24-25. (canceled)
